(19) United States
(12) Patent Application Publication
(10) Pub. No.: US 2020/0265178 A1
(43) Pub. Date: Aug. 20, 2020

(54) HYBRID FLOW EVALUATION AND OPTIMIZATION OF THERMAL SYSTEMS

(71) Applicant: Trustees of Tufts College, Medford, MA (US)

(72) Inventors: Marc Scott HODES, Cambridge, MA (US); Georgios KARAMANIS, Medford, MA (US)

(21) Appl. No.: 16/067,918

(22) PCT Filed: Jan. 5, 2017
(86) PCT No.: PCT/US17/12257

§ 371 Date: Jul. 3, 2018

Related U.S. Application Data
(60) Provisional application No. 62/274,996, filed on Jan. 5, 2016.

(51) Int. Cl. G06F 30/28; H05K 7/20; F28F 13/06

(52) U.S. Cl. CPC G06F 30/28; F28F 13/06; H05K 7/20281

(57) ABSTRACT

An approach to optimization of a thermal system includes applying computational fluid dynamics to precompute and store data for a set of canonical structures of heat transfer elements, and then using a flow network model to optimize dimensions and structures of the heat transfer elements of a thermal system in an optimization procedure that makes use of the stored data for the canonical structures.

### CROSS-REFERENCE TO RELATED APPLICATIONS

This application claims the benefit of U.S. Provisional Application No. 62/274,996, filed Jan. 5, 2016, the contents of which are incorporated herein by reference.

### BACKGROUND

This invention relates to rapid evaluation and optimization of thermal systems using a hybrid approach combining flow network modeling (FNM) and computational fluid dynamics (CFD) approaches.

Certain components, such as microprocessors and power converters, dissipate the majority of the heat produced in circuit packs used for computations and telecommunications in data centers. These components generally have heat sinks attached to them, typically with longitudinal fins, used for cooling. Air, water or other fluid coolant, often cooled to sub-ambient temperatures outside the circuit pack flows through the gaps between the fins to provide cooling. To reduce energy costs for cooling, the heat sinks in the circuit pack should be simultaneously optimized to maximize the inlet temperature of the coolant. Indeed, data centers consume 2% of the electricity in the U.S. and up to half of this is used for cooling purposes. Raising the inlet temperature of the coolant would reduce this number.

Presently it is not practical to simultaneously optimize all of the heat sinks in, say, a circuit pack, or all of the fin spacings in, say, a car radiator. In principle the optimization could be done using Computational Fluid Dynamics (CFD) software. However, one simulation using such software typically takes between tens of minutes and several hours. The number of simulations required to simultaneously optimize the heat sinks can't be performed with today's fastest computers in a realistic amount of time, if at all. Another software tool on the market is referred to as Flow Network Modeling (FNM). Using FNM modeling an approximate solution for the temperatures of all of the components in a circuit pack may be very rapidly (within seconds) obtained, but it is based upon vendor specifications, simplified correlations or CFD simulations for the quantitative characteristics of heat sinks. It is to be noted that the CFD and FNM industry has more than 1 billion USD of revenue.

### SUMMARY

In one aspect, in general, a new approach combines CFD and FNM to enable an approximate simultaneous optimization of all of the heat sinks in a circuit pack in an extremely rapid manner, for instance in minutes of computation on a computer. The approach involves first performing banks of dimensionally scaled CFD simulations that completely characterize the flow and heat transfer characteristics of (e.g., fully-shrouded) longitudinal fin heat sinks as a function of one or more of their fin thickness, fin spacing, height, length and base thickness and the thermophysical properties of the heat sink material and the coolant and the pressure drop across the heat sink. This is a time consuming endeavor that may require several months of computing time. However, once it is complete, no further simulations are required and the CFD results may be embedded into an FNM simulation. This make the FNM simulation determined by ab optimization algorithm far more accurate than using previous approaches and directly enables a bank of FNM simulations to be rapidly (e.g., within minutes) executed to approximately simultaneously optimize all of the heat sinks in a circuit pack.

It is to be noted that there are various types of flow through longitudinal fin heat sinks, such as laminar flow, turbulent flow, and laminar and then turbulent flow in the same heat sink. All such flows may be in the context of forced convection or natural convection. Banks of simulations are run for each case. Additionally, other types of heat sinks, such as pin fin heat sinks, are also be characterized. The most common case is laminar forced convection through longitudinal fin heat sinks. More flow regimes and heat sink geometries (types of heat sinks) can be used.

Generally, as introduced above, a problem addressed by one or more embodiments is to optimize the configuration of heat transfer elements to transfer heat between a fluid and a set of heat sources (or sinks). In some embodiments, the heat transfer elements are heat sinks (e.g., finned or pinned metal heat sinks) and the heat sources are electronic circuits, and the fluid is air that is forced to flow over the heat sinks. In some examples, the system is substantially two-dimensional with the fluid flow passing along one of the two dimensions, for example, as is often the case for cooling of a “blade” computer. In other embodiments, three-dimensional structures are optimized using the approach.

The optimization can address various utility criteria. For example, an objective may be to reduce inlet air temperature while satisfying maximum temperature constraints for the cooled devices. Other examples of criteria are to minimize required air flow, minimize mass or volume of the heat sinks for a prescribed inlet coolant temperature (e.g., for a weight or volume sensitive electronics packs), or maximize reliability or performance of the components and/or minimize volume or weight of heat sinks. Additionally, the technology proposed is not limited to use for sizing heat sinks in circuit packs; it could be used to, e.g., size those in a desktop or laptop computer or other heat-dissipating electronics device or non-electrical devices, such as a car radiator or high power transformers in power plants

The characteristics of the thermal system that are modified in the optimization can include values of dimensional characteristics of heat sinks. For example, in the case of fully-shrouded finned heat sinks, the spacing, height and thickness of fins, overall width and length, thickness of a base. The characteristics can also include material characteristics, including selection from a set of predefined materials (e.g., aluminum, copper, etc.) and coolants. The characteristics can also include a type of heat transfer element (e.g., longitudinal finned heat sink versus pin-fin based heat sink).

The characteristics of the thermal system that are modified in the optimization can in some embodiments include locations of the heat transfer elements. For example, a circuit layout may be amendable to modification to move the heat sources, and/or the heat transfer elements can be configured to transport heat from one location to another (e.g., via a heat pipe arrangement).

In some embodiments, the optimization approach makes use of a characterization of the thermal system as a discrete set of regions. For example, in the case of a substantially two-dimensional system (e.g., a blade computer), the regions may be two dimensional regions (e.g., rectangular regions) of the electronics system, with some of these regions corresponding to heat transfer elements and other of the regions corresponding to free space. A flow network model represents fluid flow across the regions. The regions that are not associated with the heat transfer elements have a predetermined flow versus pressure drop relationship (e.g., a flow resistance). In some examples, this relationship is a linear relationship represented by a scalar flow resistance. In some examples, these regions do not source or sink heat, however in other examples, it is possible for these regions to have predetermined heat transfer relationships that determine operational heat transfer, for example, characterizing the device temperature resulting from a particular heat dissipation rate, input temperature and a flow rate through the region (e.g., a uniform heat transfer coefficient or a heat source for each individual region). The regions not associated with the heat transfer elements may also comprise fans, pumps, blowers, etc.

Regions of the flow network model that represent heat sink elements have flow resistance and thermal resistance that depend on the thermophysical properties of the heat sink material and the coolant along with the dimensional geometric parameters of the heat sink. These dimensional geometric parameters that dictate the flow and the thermal resistances (e.g., maximum temperature of heat sink minus inlet temperature of coolant divided by heat rate dissipated by heat sink) of each (e.g., fully-shrouded) longitudinal-fin heat sink (LFHS) include:
fin height
fin thickness
fin spacing
heat sink length
heat sink width
base thickness

In some embodiments, the height of the fins and the width of each heat sink are prescribed and the system solves for the optimal fin thickness and spacing, and length of the heat sink. The number of fins follows from the fin thickness and spacing, and the width of the heat sink. Alternatively, if the weight of the heat sink is prescribed, the assumption for prescribed width is relaxed and the system solves also for the optimal width as well. In some embodiments, in addition to determining an optimal fin configuration, an optimal heat sink base thickness is also determined (i.e., recognizing that changing the base thickness may spread heat more or less thereby changing the overall heat transfer characteristics, with there being an optimum thickness).

As introduced above, prior to optimization of the thermal system represented by the flow network model, a number of dimensionally scaled CFD simulations are performed for various canonical structures, for instance characterized by ratios of dimensions, ratio of thermal conductivity, fluid Prandtl number etc., and for various operating points, for instance characterized by absolute or scaled pressure drops and/or fluid flow rate across the heat sink, and the resulting fluid flow and thermal characteristics, for instance characterized by Poiseuille number, conjugate Nusselt number, etc, and the results of these simulations are stored in tabular form associating each canonical configuration (i.e., the canonical structure and operating point) with flow and thermal characteristics.

During some implementations of an optimization procedure, at each iteration, the particular configurations of the heat sinks (e.g., dimensions, locations, etc.) are considered. For each of the heat sinks, the actual dimensions are mapped to one of the stored canonical structures, and the flow and thermal characteristics for the canonical structure are transformed according to the mapping to yield the flow and thermal characteristics for the actual dimensions. These flow and thermal coefficients are used in the flow network model to determine the overall characteristics of the thermal system (e.g., operating temperatures of the devices cooled by each of the heat sinks, fluid flow across each heat sink, input fluid temperature, etc.).

In at least some optimization approaches updated configurations of the heat sinks are determined from the result of the flow network model computation (e.g., by incremental adjustment and/or gradient search) with the goal of improving the overall utility of the configuration of the heat sinks. The utility may be defined in a variety of ways, for example, according to the required intake temperature, required overall flow rate, weight of the heat sinks, etc.).

Various computer-implemented computational approaches to optimization may be used, for instance the Nelder-Mead method and Simulated Annealing. In some implementations a gradient approach is used, with the gradient being computed using the flow network model and/or parameter sensitivities determined from the CFD analyses.

In addition to common air cooling schemes where air flows through whole circuit pack in addition to heat sinks a technique called “indirect liquid cooling” can be used in which cold plate type heat sinks are attached to components such as microprocessors. In such a case the cold plates have, say, longitudinal or pin fin heat sinks in them. But the fluid is piped through only the cold plates and it is liquid coming in (and can be single-phase where it stays liquid or two-phase where some of it vaporizes) during cooling.

In another aspect, in general, an approach to optimizing a thermal system includes the steps:
1. Precompute and store data characterization of canonical heat sink configurations (e.g., dimensionless tabulated data for various materials and fluids, heat sink type, flow regimes)
2. Input of a flow network model representation of the thermal system to be optimized, with subset of elements of the model corresponding to heat sinks of the system
3. Input optimization variables, constraints, and utility function to optimize
4. Iterate:
   (a) Access precomputed stored data (from 1) for canonical heat sinks corresponding to flow network elements
   (b) Transform canonical data to characterization of specifically dimensioned heat sinks
   (c) Solve flow network model to determine fluid and heat flow, and achieved utility (e.g., required input temperature)
   (d) Adjust parameters of heat sinks (overall dimensions, fin dimensions, location, etc.) to improve utility

In some aspects, the method comprises only the precomputation step 1, which is independent of any particular thermal system to be optimized. In another aspect, the method excludes the precomputation step 1 and comprises only steps 2-4, which are directed to a particular thermal system being optimized.

In some implementations, an additional final step is performed comprising a full CFD simulation of the thermal system, optionally including further adjustment of the parameters to improve utility. Implementations may use software, with instructions stored on machine-readable media, with the instructions causing a computer to perform the methods described above.

One or more embodiments are applicable to the design of micro- or nano-scale heat sinks/exchangers for single-phase gas flows. In such embodiments, the canonical problems that need be solved for dimensionless flow and thermal resistances (friction factor times Reynolds number product and Nusselt number) impose molecular slip boundary conditions (on velocity and temperature) at the solid-fluid interfaces when the Knudsen number of the gas is sufficiently high. For extremely, high Knudsen numbers, the continuum assumption breaks down and molecular dynamics simulations are used to compute the dimensionless flow and thermal resistances.

Advantages of the approach is that as compared to conventional technical approaches, such as purely CFD or purely FNM approaches, the present techniques can produce close to equal accuracy with much reduced computation, and/or increased accuracy (i.e., improved designs) for a close to equal computational cost. That is, the approach is more accurate than FNM alone and far more fast than CFD alone. In many cases it may be nearly as accurate as CFD and nearly as fast as FNM.

In some software embodiments, the approach is embodied is a “standalone” software application. In another software embodiment, the software works in conjunction with another software application, for example, that implements FNM functions and use interface functions, and interfaces with that other software application via files or other communication approaches (e.g., as a “plug-in”).

Other features and advantages of the invention are apparent from the following description, and from the claims.

### DESCRIPTION OF DRAWINGS

FIG. 1 is a perspective view of an unconfined longitudinal-fin heat sink (LFHS).

FIG. 2 is a perspective view of a circuit pack with heat sinks.

FIG. 3 is a perspective view of an liquid-cooled circuit pack.

FIG. 4 is a plan view of the circuit pack of FIG. 2.

FIG. 5 is a flow resistance network corresponding to the circuit pack shown in FIG. 2 and FIG. 4.

FIG. 6 is a cross-section view of a half-fin segment of a heat sink.

FIG. 7 is a cross-section view of a half-fin segment with an isothermal base.

FIG. 8 is a graph of conjugate mean Nusselt number versus dimensionless fin spacing and thickness.

FIG. 9 is a graph of an optimal dimensionless fin spacing as a function of dimensionless fin thickness.

FIG. 10 is a graph of thermal resistance per unit width as a function of dimensionless fin separation and thickness.

FIG. 11 is a flow diagram illustrating an optimization procedure.

### DETAILED DESCRIPTION

### 1 Overview

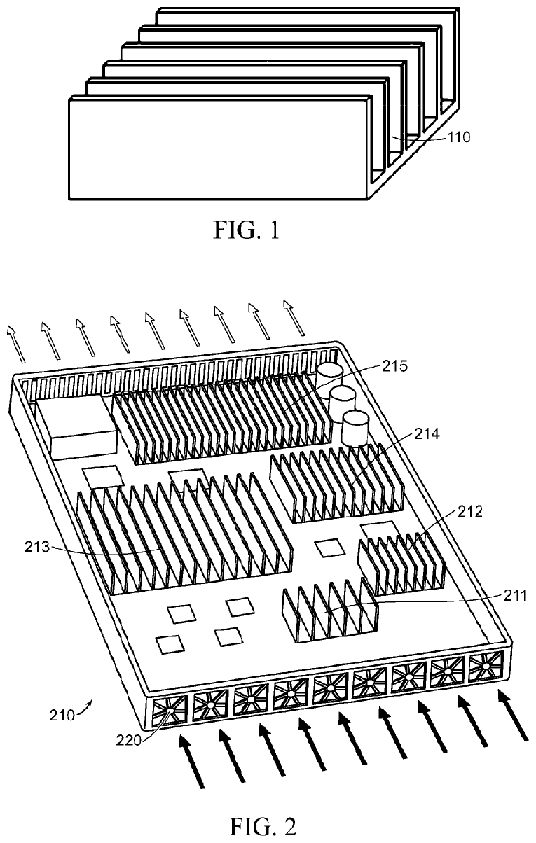

Longitudinal-fin heat sinks (LFHSs) are ubiquitous in cooling (or other heat transfer) applications. A schematic of a LFHS 110 is shown in FIG. 1. One representative application is cooling of a circuit pack 210, say, a blade server for computing or one found in telecommunications hardware, is shown in FIG. 2. Five high power (heat) dissipating components 211-215 are shown in FIG. 2, each with a longitudinal fin heat sink (LFHS) 110 attached to it. Note that LFHSs are a representative heat sink geometry. Other types of heat sink geometries, such as pin fin heat sinks, offset strip fin heat sinks, and louvered fin heat sinks are also in use. The present approach accommodates arbitrary types of heat sinks and it also applies to the cooling of components that do not have a heat sink on them. The power-dissipating components 211-215 may include, for example, microprocessors, memory, graphics processors, field programmable gate arrays (FPGAs), power converters, optical components, optoelectronic components and radio frequency amplifiers. Data centers used by telecommunications companies, computing and storage companies and any large entity requiring computing and/or communications may have hundreds to tens of thousands of such circuit packs. Cooling them accounts for about 1% of the electricity consumed in the U.S. It is noted that the approaches described in this document may be applied to other types of thermal systems, say that for cooling a desktop computer or to size the fins on a car radiator.

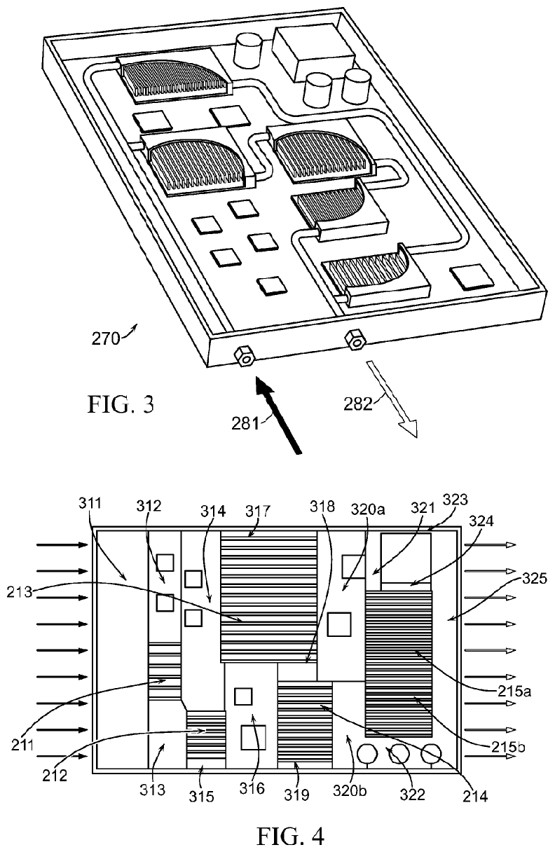

Air, which may be cooled to sub-ambient temperatures, is driven by fans 220 through the circuit pack 210, such as that shown in FIG. 2, and cools the heat sinks (and thus components attached to them) inside a circuit pack. The air also cools lower power dissipation components, such as the capacitors shown by the cylinders in FIG. 2, that do not require dedicated heat sinks and tend to operate well below their maximum operating temperatures. Other coolants, such as water or refrigerants, are used as well and in some cases the coolant is routed directly to each heat sink in separate conduits. An example of liquid-cooled circuit pack 270 is shown in FIG. 3. Cool liquid 281 is passed via conduits to the heat sinks, emerging as warmed liquid 282. Coolant may be in the liquid phase, vapor phase or the phases may coexist.

Approaches described in this document combine CFD and FNM to A) enable FNM to accommodate any heat sink as opposed to those previously externally characterized and B) enable an approximate simultaneous optimization of the geometry of all of the heat sinks in a circuit pack in an extremely rapid manner, i.e., minutes. (By “any” heat sink we mean those that have been characterized by CFD using the present approach and embedded in FNM.) Banks of dimensionally-scaled CFD simulations are preformed that completely characterize the flow and heat transfer characteristics of, for example, LFHSs as a function of their fin thickness, fin spacing, fin height, fin length, etc. and the thermophysical properties of the coolant. This may be a time consuming endeavor that requires, perhaps, several months. However, once it is complete, no further CFD simulations are required and the results may be embedded into an FNM simulation in the form of a look-up table. Note that this approach is different than approaches where CFD simulations are repeatedly performed to characterize a heat sink each time a change in its geometry is to be made. Embedding of CFD simulations in FNM makes FNM far more accurate than at present and directly enables a bank of FNM simulations to be rapidly (within minutes) executed to (approximately) simultaneously optimize all of the heat sinks in a circuit pack. A brute-force approach may be used for such optimizations by making it possible to run numerous FNM cases. However, standard multi-variable optimization techniques, for example the Nelder-Mead method, can also be used to determine, for example, the true optimal physical dimensions of the heat sinks in the prescribed parameter space. Once the approximate optimization is performed a more accurate calculation of the temperatures of all of the components in a circuit pack may be obtained by CFD simulations. A salient point that is re-emphasized here is that CFD simulations in and of themselves are too time consuming to provide even an approximate optimization of the geometry of the heat sinks in a circuit pack when they are to be simultaneously optimized. Even optimizing a single heat sink by CFD is a very time consuming tasks, requiring typically tens of hours of personal time and even more computing time.

It should be recognized that LFHSs are one geometry of heat sinks. To make the hybrid CFD-FNM approach as general as possible, a series of canonical CFD problems are solved. It should be appreciated that it would not be practical to perform the CFD pre-computation for all possible physical configurations without determining the much smaller number of canonical configurations that are actually addressed. From a FNM execution perspective, Poiseuille (Po) and Nusselt (Nu) numbers may be used as the dimensionless parameters that characterize flow resistances and thermal resistances utilized in FNM. In general Nu numbers utilized are preferably conjugate Nusselt numbers, i.e., they should account for both conduction in the solid portion of the heat sink and convection to the fluid. Expressions for Po and Nu as a function of the relevant independent variables in dimensionless form are tabulated for various flow regimes, i.e., laminar flows, turbulent flows and laminar flows in a portion of a heat sink and turbulent flows in the remainder. The flow may be assumed fully-developed or, more generally, assumed to be simultaneously developing. Single-phase or multi-phase flows may be considered and heat transfer may be by forced and/or natural convection. Radiation heat transfer effects may also be captured. Various additional effects, such as bypass flow through gaps between the tops of the fins and a shroud and bypass flow around the sides of heat sinks may also be captured as may the effects of spreading resistances in the base of heat sinks. Upon use of the Buckingham Pi Theorem, it is clear to those skilled in the art what independent dimensionless parameters, for instance, dimensionless fin thickness, spacing and length, Prandtl number of the coolant, etc. may need to be captured in the expressions for Po and Nu as a functions of the physics to be captured in a particular canonical problem. A important additional or alternative type of heat sink that may be considered is a pin fin heat sink, which is insensitive to the direction of the flow of the coolant.

An example optimization is presented here in the context of the circuit pack illustrated in FIG. 2. A typical constraint on such an optimization problem is the maximum pressure drop prescribed to pump air through such a circuit pack or the pressure versus volumetric flow rate of the fan(s) driving the air flow through the circuit pack. The objective of the optimization is the decision of the user of the algorithm. It could be, for instance, the maximization of the inlet temperature of the air entering the circuit pack such that all of the components in the circuit pack meet their performance and reliability specifications. This would imply that all of the components operate at their maximum operating temperature as specified by the vendors who manufacture them. (For example, a typical Intel microprocessor must operate at 85° C. to meet its performance and reliability specifications.) A reason a user of the present approach would be interested in such an optimization is that maximizing the inlet air temperature through the circuit pack can enable one to minimize the load on the refrigeration system required to cool the air before it enters the circuit pack. This would minimize the electricity consumed for cooling. In some cases, the optimization may allow so-called free cooling, where air at ambient temperature suffices to cool the components in the circuit pack. Alternatively, the objective function could be to maximize the reliability of the circuit pack. Then, all of the components in the circuit pack may need to operate at the same temperature difference below their maximum operating temperature, which itself may vary from component-to-component. This is because the reliability of components decreases in a highly nonlinear manner as their maximum operating temperatures are approached. It should be understood that yet other objectives may be optimized using the present approach.

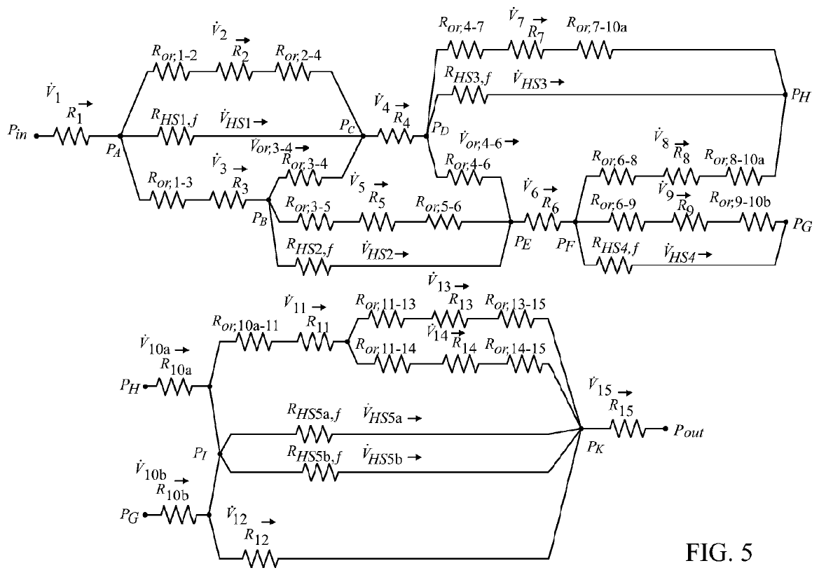

FIG. 4 shows the circuit pack in FIG. 2 and, additionally, a series of regions, including regions associated with heat sinks 211-215 as well as surrounding regions 311-326. Each region has a corresponding flow resistance (R). Flow resistance is equal to pressure drop across a region divided by volumetric flow of fluid through it. A variety of ways to calculate such flow resistances are well known to the FNM community and, in the case of heat sinks, follow from Po numbers. FIG. 5 show a flow resistance network corresponding to the circuit pack shown in FIG. 2 and broken into flow regions in FIG. 4.

For a particular configuration of heat sinks, there are two problems that are solved in order to determine the performance characteristics of the configuration. First, fluid flow is determined using the network model, for example, using the flow resistance network shown in FIG. 5. In this flow model, the parameters that determine the fluid flow (and associated pressure drops) for each of the heat sinks include the inlet and outlet pressures, pᵢₙ and pₒᵤₜ, flow resistance for each heat sink, R_{HSi,f}, and flow resistances at each of the orifices between regions, R_{or,i-j}. Having these flow resistances enables the flows to be determined by solving a set of linear equations based on conservation of mass and conservation of momentum constraints. The pressures (P) at each node in the flow resistance network and the volumetric flow rate of fluid across each resistance within it (\dot{V}) are the output parameters of the FNM simulation.

Having solved for the flow rates and/or pressure drops for each of the heat sinks, the thermal problem of determining the heat transfer through each of the heat sinks makes use of the inlet and outlet temperatures, Tᵢₙ and Tₒᵤₜ, and the base temperature or the heat transfer rate for each heat sink, T_{HSi,base} or \dot{q}_{HSi}, as well as the thermal resistance of each heat sink, R_{HSi,t}. In particular, the temperature of the components follows from an energy balance utilizing their thermal resistances, which themselves are dependent upon the tabulated conjugate Nusselt and Poiseuille numbers for the canonical heat sink problems.

One approach to optimization of the heat sink configurations is to use a current set of flow and thermal resistances, R_{HSi,f} and R_{HSi,t} to solve for the flows and temperatures of the system. For an incremental change in heat sink configuration (e.g., a change of fin thickness and fin spacing), new values of the flow and thermal resistances are determined from the precomputed tables of canonical configurations introduced above. From these new values, new flow and temperature conditions may be computed, and an overall objective function computed. Various optimization control approaches to determine the sequence of incremental changes can be used, for example, Simulated Annealing, to optimize the objective function. Moreover, an efficient and simultaneous optimization of the geometry (e.g., fin spacing, fin thickness, fin height, fin base thickness, heat sink length, etc.) of all of the heat sinks in the circuit pack may be obtained as discussed above. Either a brute-force approach or one based on a multi-variable optimization algorithm may be used.

Based on the approach outlined above, it should be appreciated that a very important aspect of the present approach is the computation of the tables of thermal and flow properties for the set of canonical configurations. These tables are referenced during iterations of the optimization procedure. As introduced above, these tables may be indexed by dimensionless quantities that may be determined from the actual dimensions of the heat sinks.

In at least some embodiments, for example, the thermal resistance per unit width of a fully-shrouded LFHS with an isothermal base is expressed in dimensionless form as a function of the conjugate mean Nusselt number. Then, a computer-implemented computational procedure requiring relatively few algebraic computations is used to compute the optimal fin spacing, thickness and length that minimize its thermal resistance under conditions of simultaneously developing laminar flow Prescribed quantities may include the density, viscosity, thermal conductivity and specific heat capacity of the fluid, the thermal conductivity and height of the fins, and the pressure drop across the LFHS. A uniform heat transfer coefficient is not necessarily assumed. Rather, the velocity and temperature fields are fully captured by numerically solving the conjugate heat transfer problem in dimensionless form to compute the conjugate mean Nusselt number for simultaneously developing flow. The results are relevant, for instance, to electronics cooling applications where heat spreaders or vapors chambers are utilized to make the base of heat sinks essentially isothermal.

Generally, increasing heat dissipation by electronic components via LFHSs requires determining the optimal values of the geometric parameters of LFHSs that minimize their thermal resistance (Rₜ) defined as

$${R}_{t} = \frac{{T}_{base , max} - {T}_{b , i}}{q} \qquad ( 1 )$$

where T_{base,max} is the maximum temperature along the base of the heat sink, T_{b,i} is the inlet fluid temperature and q is the rate of heat dissipation.

The literature for the case of hydrodynamically- and thermally-developed laminar flow can be divided into two categories. The first minimizes Rₜ assuming a uniform heat transfer coefficient along the fins [3, 11, 6, 7]. However, Sparrow et al. [10] showed that this assumption is generally invalid. Indeed, Sparrow et al. [10] solved the conjugate heat transfer problem and computed the heat transfer coefficient as a function of the location along the fin, which was negative near the tip of a sufficiently slender fin. Furthermore, their results show that due to the relatively low velocity of the fluid in the area adjacent to the base, the heat flux near the root of the fin and from the prime surface is modest compared to that from the higher part of the fin. This is contrary to the notion imposed by the constant heat transfer coefficient assumption that the root is the most thermally active part of the fin. The second category of previous work minimizes Rₜ by solving the conjugate problem multiple times either in dimensional or in dimensionless form, but the results are relevant to the specific problem [8, 4, 12].

The present approach makes use of a closed-form expression that allows Rₜ to be evaluated algebraically over a relevant range of dimensionless parameters by utilizing a dense tabulation of conjugate parameters computed generally using an approach related to that used by Sparrow et al. [10]. An optimization method is then used to determine the optimal fin spacing (sₒₚₜ) and thickness (tₒₚₜ). Our analysis assumes an isothermal heat sink base, an adiabatic shroud and constant thermophysical properties, and that natural convection, viscous dissipation, axial conduction in the fins and fluid, and temperature differences across the thickness of the fins are negligible. These assumptions are valid in certain applications, e.g., an LFHS with an embedded vapor chamber in its base that is fully-shrouded by a plastic case.

An embodiment of the CFD analysis used as the basis for computing the tables for the canonical configurations is described in the following sections. In Section 2 a possible set of relevant dimensionless parameters for the problem at hand is determined by applying the Buckingham Pi theorem. A specific case of an LFHS for an isothermal base is addressed in Section 3. Then, in Subsection 3.1 the number of the dimensionless parameters is reduced by two by assuming an isothermal base and we present the dimensionless formulation of the corresponding conjugate heat transfer problem. Next, Subsection 3.2 defines and presents the formulation of the conjugate mean Nusselt number (N̅u̅). In Subsection 3.3 a closed-form expression for the thermal resistance per unit width of the heat sink that involves only N̅u̅ and relevant prescribed dimensionless parameters is developed. This expression allows R′ₜ to be evaluated algebraically over a relevant range of the dimensionless independent variables by utilizing a dense tabulation of N̅u̅. The tabulation of N̅u̅ is performed in Subsection 3.4 and the computed results are discussed in Subsection 3.5. Finally, in Subsection 3.6 we present an example for the optimization algorithm where we determine the optimal fin spacing and thickness of a cooper-LFHS that is cooled by air, but the same process can be also applied to determine the optimal length of the fins.

An important aspect of the present approach is that once extensive dense tables of N̅u̅ have been computed and become available in [2], sₒₚₜ, tₒₚₜ and Lₒₚₜ can be determined algebraically using the derived expression for R′ₜ without the need to solve the conjugate heat transfer problem.

It should be understood that other embodiments may use other approaches to computing the required tables without deviating from the overall new approach presented in this document. For example, different parameters may be used to index the tables, and different quantities may be stored in the tables, and different analytical approaches may be used in the computation of the quantities in the tables.

### 2 Dimensional Analysis

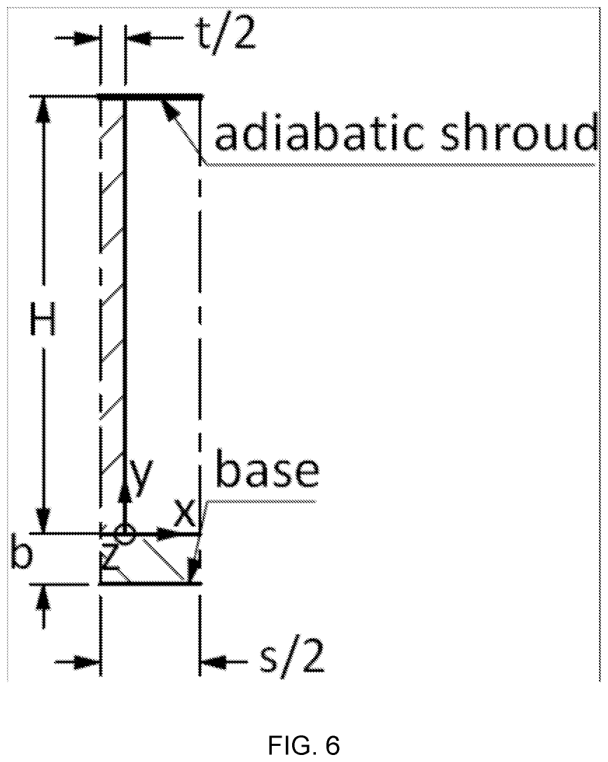

In this section we perform a dimensional analysis to derive a set of dimensionless parameters that determine the conjugate mean Nusselt number. Recalling the assumption that the width of the heat sink is much greater than the sum of the fin separation and fin thickness, W>>s+t, such that edge effects can be ignored, it suffices to solve the governing equations on the domain depicted in FIG. 6. This domain comprises a half fin and a half channel along with the corresponding part of the base.

Given conditions of steady and hydrodynamically developing laminar flow with constant thermophysical properties and forced convection, the relevant forms of the continuity and the Navier-Stokes equations are, respectively,

$$\begin{matrix}∇ \cdot U = 0 & ( 2 ) \\ ( U \cdot ∇ ) U = - \frac{1}{ρ} ∇ p + \frac{μ}{ρ} {∇}^{2} U & ( 3 )\end{matrix}$$

where V=∂/∂x+∂/∂y+∂/∂z, p, ρ and μ, are the pressure, density and dynamic viscosity, respectively, and

$$U = [ \begin{matrix}u \\ v \\ w\end{matrix} ] \qquad ( 4 )$$

is the velocity vector where u, v and w are the velocity components in the x, y and z-direction, respectively.

The boundary conditions are

$$\begin{matrix}U = 0 , for x = 0 , y = 0 and y = H & ( 5 ) \\ \frac{\partial U}{\partial x} = 0 , for x = \frac{s}{2} & ( 6 ) \\ U = [ \begin{matrix}0 \\ 0 \\ {w}_{i n}\end{matrix} ] , for z = 0 & ( 7 ) \\ p = 0 , for z = L & ( 8 )\end{matrix}$$

where wᵢₙ is the uniform inlet streamwise velocity.

The relevant forms of the thermal energy equations for the fluid, the fin and the base are, respectively,

$$\begin{matrix}U \cdot ∇ T = \frac{k}{ρ {c}_{p}} {∇}^{2} T & ( 9 ) \\ {∇}^{2} {T}_{f} = 0 & ( 10 ) \\ {∇}^{2} {T}_{b a s e} = 0 & ( 11 )\end{matrix}$$

where T, T_{f} and T_{base} are the temperature of the fluid, the fin and the base, respectively, and k and cₚ are the thermal conductivity and specific heat at constant pressure of the fluid, respectively.

The boundary conditions for the thermal energy equation for the fluid are

$$\begin{matrix}\frac{\partial T}{\partial x} = 0 for x = \frac{s}{2} & ( 12 ) \\ \frac{\partial T}{\partial y} = 0 for y = H & ( 13 ) \\ T = {T}_{b , i} for z = 0 & ( 14 )\end{matrix}$$

along with the 2 conjugate boundary conditions that impose the continuity of the temperature and the heat flux at the two solid-liquid interfaces along the fin and the prime surface, respectively,

$$\begin{matrix}T = {T}_{f} for x = 0 & ( 15 ) \\ k \frac{\partial T}{\partial x} = {k}_{f} \frac{\partial {T}_{f}}{\partial x} for x = 0 & ( 16 ) \\ T = {T}_{b a s e} for y = 0 & ( 17 ) \\ k \frac{\partial T}{\partial y} = {k}_{b} \frac{\partial {T}_{b a s e}}{\partial y} for y = 0 & ( 18 )\end{matrix}$$

The boundary conditions for the fin are given by Eqs. 15 and 16, the equations

$$\begin{matrix}\frac{\partial {T}_{f}}{\partial x} = 0 for x = - \frac{t}{2} & ( 19 ) \\ \frac{\partial {T}_{f}}{\partial y} = 0 for y = H & ( 20 ) \\ \frac{\partial {T}_{f}}{\partial z} = 0 for z = 0 and z = L & ( 21 )\end{matrix}$$

and the conjugate boundary condition for the heat conduction at the base-fin interface

$$\begin{matrix}{T}_{f} = {T}_{b a s e} for y = 0 & ( 22 ) \\ {k}_{f} \frac{\partial {T}_{f}}{\partial y} = {k}_{b} \frac{\partial {T}_{b a s e}}{\partial y} for y = 0 & ( 23 )\end{matrix}$$

The boundary conditions for the base are given by Eqs. 17, 18, 22 and 23 along with

$$\begin{matrix}A {T}_{b a s e} + B {k}_{b} \frac{\partial {T}_{b a s e}}{\partial y} = F for y = 0 & ( 24 ) \\ \frac{\partial {T}_{b a s e}}{\partial x} = 0 for x = - \frac{t}{2} for x = \frac{s}{2} & ( 25 ) \\ \frac{\partial {T}_{b a s e}}{\partial z} = 0 for z = 0 and z = L & ( 26 )\end{matrix}$$

were A (x, z), B (x, z) and F (x, z) can be arbitrary but need to be symmetric with respect to the boundaries at x=−t/2 and x=s/2. Equation 24 reduces to the isothermal boundary condition for A=1, B=0 and F equal to the prescribed constant temperature. Also, Eq. 24 reduces to the isoflux boundary condition for A=0, B=−1 and F equal to the prescribed heat flux. If either of A, B or F are not symmetric with respect to the aforementioned boundaries, e.g., when there is one or multiple isolated heat sources attached to the base spanning over more than half channel, the conjugate heat transfer problem must be solved on the specific appropriate domain that might be the whole heat sink.

Equations 2-26 show that the conjugate mean Nusselt number is a function of 5 geometric parameters (H, s, t, L, b), (height, fin separation, fin thickness, length, and base thickness), 4 thermophysical properties of the fluid (p, μ, cₚ, k), (density, viscosity, specific heat, thermal conductivity), 1 thermophysical property of the base (k_{b}), (thermal conductivity of the base), 1 thermophysical property of the fin (k_{f}), (thermal conductivity), and 2 external parameters namely wᵢₙ, (inlet velocity), and the prescribed thermal boundary condition at the base of the LFHS as per Eq 24. Therefore, for each type of prescribed thermal boundary condition, the Buckingham Pi Theorem indicates that the conjugate mean Nusselt number is a function of 8 independent dimensionless parameters and a valid set of them is

$$\begin{matrix}\tilde{s} = \frac{s}{H} & ( 27 ) \\ \tilde{t} = \frac{t}{H} & ( 28 ) \\ \tilde{L} = \frac{L}{H} & ( 29 ) \\ \tilde{b} = \frac{b}{H} & ( 30 ) \\ Pr = \frac{{c}_{p} μ}{k} & ( 31 ) \\ {K}_{b} = \frac{{k}_{b}}{k} & ( 32 ) \\ {K}_{f} = \frac{{k}_{f}}{k} & ( 33 ) \\ {Re}_{m} = \frac{ρ Δ p {H}^{2}}{{μ}^{2}} & ( 34 )\end{matrix}$$

where Δp is the prescribed pressure drop and \tilde{s}, \tilde{t}, \tilde{L} and \tilde{b} are the dimensionless fin spacing, fin thickness, fin length and base thickness, respectively. Moreover, Pr, K_{b} and K_{f} are the Prandtl number and the ratios of thermal conductivities of the base and the fin, respectively. Reₘ is a modified Reynolds number where the characteristic length and the scale of the velocity are H and (ΔpH/μ), respectively.

Finally, three aspects of the present analysis are emphasized. First, Reₘ is a more relevant dimensionless quantity for the tabulation of the conjugate mean Nusselt number than the Reynolds number based on the hydraulic diameter (Re_{D}_{ₕ}), where

$$\begin{matrix}{Re}_{{D}_{h}} = \frac{ρ \overline{w} {D}_{h}}{μ} & ( 35 ) \\ {D}_{h} = \frac{2 s H}{s + H} & ( 36 )\end{matrix}$$

and w̅ is the mean streamwise velocity. This is because Δp is generally the prescribed variable for the operating point of a given LFHS and w̅ is the unknown. The second aspect that is emphasized is that the present analysis is valid for arbitrary values of the Péclet number (Pe) and the Biot (Bi) number given that it takes into consideration the axial conduction term in the thermal energy equation for the fluid and that it solves the diffusion equation in the fin. Thirdly, the analysis accounts for heat conduction through the prime surface to the fluid.

### 3 Conjugate Mean Nusselt Number for Isothermal Base

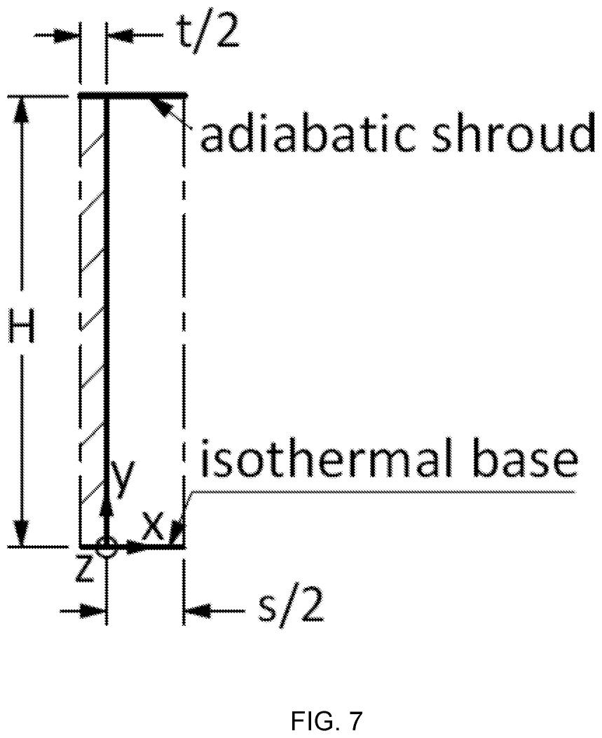

In many applications where, e.g., a vapor chamber is installed in the base of an LFHS or if b or k_{b} are sufficiently high, the base of the heat sink becomes essentially isothermal. Thus, we do not need to solve the conduction problem for the base, and since b and k_{b} are irrelevant the number of the independent dimensionless parameters reduces to 6, namely: \tilde{s}, \tilde{t}, \tilde{L}, Pr, K_{f} and Reₘ. As such, we only need to solve the conjugate heat transfer problem on the domain depicted in FIG. 7.

### 3.1 Dimensionless Hydrodynamic and Thermal Problems

Denoting nondimensional variables with tildes and defining

$$\begin{matrix}\tilde{x} = \frac{x}{H} & ( 37 ) \\ \tilde{y} = \frac{y}{H} & ( 38 ) \\ \tilde{z} = \frac{z}{H} & ( 39 ) \\ \tilde{U} = \frac{μ}{Δ p H} U & ( 40 ) \\ \tilde{p} = \frac{{μ}^{2}}{ρ {H}^{2} Δ {p}^{2}} p & ( 41 ) \\ \tilde{∇} = H ∇ & ( 42 )\end{matrix}$$

Equations 2 and 3 become, respectively,

$$\begin{matrix}\tilde{∇} \cdot \tilde{U} = 0 & ( 43 ) \\ ( \tilde{U} \cdot \tilde{∇} ) \tilde{U} = - \tilde{∇} \tilde{p} + \frac{1}{{Re}_{m}} {\tilde{∇}}^{2} \tilde{U} & ( 44 )\end{matrix}$$

subject to the boundary conditions

$$\begin{matrix}\tilde{U} = 0 , for \tilde{x} = 0 , \tilde{y} = 0 and \tilde{y} = 1 & ( 45 ) \\ \frac{\partial \tilde{U}}{\partial \tilde{x}} = 0 , for \tilde{x} = \frac{\tilde{s}}{2} & ( 46 ) \\ \tilde{U} = [ \begin{matrix}0 \\ 0 \\ {\tilde{w}}_{i n}\end{matrix} ] , for \tilde{z} = 0 & ( 47 ) \\ \tilde{p} = 0 , for \tilde{z} = \tilde{L} & ( 48 )\end{matrix}$$

Defining the dimensionless temperature for the fluid and the fin as

$$\begin{matrix}\tilde{T} = \frac{T - {T}_{b a s e}}{{T}_{b , i} - {T}_{b a s e}} & ( 49 ) \\ {\tilde{T}}_{f} = \frac{{T}_{f} - {T}_{b a s e}}{{T}_{b , i} - {T}_{b a s e}} & ( 50 )\end{matrix}$$

respectively, the dimensionless thermal energy equation for the fluid becomes

$$\tilde{U} \cdot \tilde{∇} \tilde{T} = \frac{1}{{Re}_{m} P r} {\tilde{∇}}^{2} \tilde{T} \qquad ( 51 )$$

subject to the boundary conditions

$$\begin{matrix}\tilde{T} = 0 for \tilde{y} = 0 & ( 52 ) \\ \frac{\partial \tilde{T}}{\partial \tilde{x}} = 0 for \tilde{x} = \frac{\tilde{s}}{2} & ( 53 ) \\ \frac{\partial \tilde{T}}{\partial \tilde{y}} = 0 for \tilde{y} = 1 & ( 54 ) \\ \tilde{T} = 1 for \tilde{z} = 0 & ( 55 )\end{matrix}$$

and to the conjugate boundary condition at the solid-liquid interface along the fin

$$\begin{matrix}\tilde{T} = {\tilde{T}}_{f} for \tilde{x} = 0 & ( 56 ) \\ \frac{\partial \tilde{T}}{\partial \tilde{x}} = {K}_{f} \frac{\partial {\tilde{T}}_{f}}{\partial \tilde{x}} for \tilde{x} = 0 & ( 57 )\end{matrix}$$

The dimensionless thermal energy equation for the fin takes the form

\tilde{∇}²\tilde{T}_{f}=0 (58)

and the corresponding boundary conditions consist of Eqs. 56 and 57 along with

$$\begin{matrix}{\tilde{T}}_{f} = 0 for \tilde{y} = 0 & ( 59 ) \\ \frac{\partial {\tilde{T}}_{f}}{\partial \tilde{x}} = 0 for \tilde{x} = - \frac{\tilde{t}}{2} & ( 60 ) \\ \frac{\partial {\tilde{T}}_{f}}{\partial \tilde{y}} = 0 for \tilde{y} = 1 & ( 61 ) \\ \frac{\partial {\tilde{T}}_{f}}{\partial \tilde{z}} = 0 for \tilde{z} = 0 and \tilde{z} = \tilde{L} & ( 62 )\end{matrix}$$

The solution of the conjugate problem is comprised of two parts. First, Eqs. 43 and 44 are solved subject to the boundary conditions 45-48 to calculate the dimensionless velocity field. Then, Eqs. 51 and 58 are solved simultaneously subject to the boundary conditions 52-55 and 59-62 utilizing the previously computed Ũ to determine the dimensionless temperature fields of the fluid and the fin. Once, \tilde{T} is known the corresponding conjugate mean Nusselt number follows from an energy balance as per Section 3.2.

In this embodiment, the conjugate problem was solved numerically using the commercial CFD solver FLUENT® in conjunction with ANSYS Workbnech® for multiple sets of values of the of dimensionless parameters. The results are presented in Section 3.5.

### 3.2 Conjugate Mean Nusselt Number Formulation

Based on the assumption that the width of the heat sink is sufficiently large such that edge effects are irrelevant, i.e., W>>s+t, the number of the channels (n_{ch}) that are formed between consecutive fins is approximately equal to

$${n}_{c h} = \frac{W}{s + t} \qquad ( 63 )$$

The heat rate through the base of a channel (q_{ch}) is given by the expression

$${q}_{c h} = - 2 {\int }_{0}^{L} ( {\int }_{- t / 2}^{0} {k}_{f} \frac{\partial {T}_{f}}{\partial y} {\vert}_{y = 0} d x + {\int }_{0}^{s / 2} k \frac{\partial T}{\partial y} {\vert}_{y = 0} d x ) d z \qquad ( 64 )$$

From Eqs. 63 and 64, it follows that the total heat transfer rate per unit width through the base of the LFHS is

$${q}^{′} = - \frac{2}{s + t} {\int }_{0}^{L} ( {\int }_{- t / 2}^{0} {k}_{f} \frac{\partial {T}_{f}}{\partial y} {\vert}_{y = 0} dx + {\int }_{0}^{s / 2} k \frac{\partial T}{\partial y} {\vert}_{y = 0} d x ) d z \qquad ( 65 )$$

Moreover, from Newton's law of cooling we can write that

q′=h̅L(T_{base}−T_{b,i}) (66)

where h̅ is the average heat transfer coefficient.

Combining Eqs. 65 and 66, we have that

$$\overline{h} = \frac{- 2}{L ( s + t ) ( {T}_{b a s e} - {T}_{b , i} )} {\int }_{0}^{L} ( {\int }_{- t / 2}^{0} {k}_{f} \frac{\partial {T}_{f}}{\partial y} {\vert}_{y = 0} d x + {\int }_{0}^{s / 2} k \frac{\partial T}{\partial y} {\vert}_{y = 0} d x ) d z \qquad ( 67 )$$

In the present analysis the conjugate mean Nusselt number is defined as

$$\overline{Nu} = \frac{\overline{h} H}{k} \qquad ( 68 )$$

Thus, from Eqs. 67 and 68, it follows that the conjugate mean Nusselt number of an LFHS in terms of the aforementioned dimensionless quantities is given by the expression

$$\overline{Nu} = \frac{- 2}{\tilde{L} ( \tilde{s} + \tilde{t} )} {\int }_{0}^{\tilde{L}} ( {\int }_{- \tilde{t} / 2}^{0} {K}_{f} \frac{\partial {\tilde{T}}_{f}}{\partial \tilde{y}} {\vert}_{\tilde{y} = 0} d \tilde{x} + {\int }_{0}^{\tilde{s} / 2} \frac{\partial \tilde{T}}{\partial \tilde{y}} {\vert}_{\tilde{y} = 0} d \tilde{x} ) d \tilde{z} \qquad ( 69 )$$

Equation 69 states that for the case at hand the conjugate mean Nusselt number is the dimensionless area averaged temperature gradient at the base of the conjugate domain, where the temperature gradient of the fin is weighted by K_{f}. That means that, the integral ∫_{-\tilde{t}/2}⁰K_{f}∂\tilde{T}_{f}/∂\tilde{y}|_{\tilde{y}=0}d\tilde{x} is of the same or higher order compared to the integral ∫₀^{\tilde{s}/2}∂\tilde{T}/∂\tilde{y}|_{\tilde{y}=0}d\tilde{x}, even if the fin tends to isothermal, i.e., ∂\tilde{T}_{f}/∂\tilde{y}|_{\tilde{y}=0}→0, since usually the thermal conductivity of the fin is significantly larger than the thermal conductivity of the fluid, i.e., K_{f}→∞. This contradicts the idea that the prime surface is more thermally active region than the root of the fin.

### 3.3 Thermal Resistance Formulation and Minimization Algorithm

Given that the base of the LFHS is isothermal, i.e., T_{base,max}=T_{base}, the thermal resistance per unit width of the heat sink becomes

$${R}_{t}^{′} = \frac{{T}_{b a s e} - {T}_{b , i}}{{q}^{′}} \qquad ( 70 )$$

Combining Eqs. 66, 68 and 70, it follows that

$${R}_{t}^{′} = \frac{1}{k \tilde{L} \overline{Nu}} \qquad ( 71 )$$

Equation 71 dictates that for prescribed thermophysical properties for the fluid and the fin (Pr,K_{f}), and pressure drop across the heat sink (Reₘ), R′ₜ is only function of \tilde{s}, \tilde{t} and \tilde{L}. Thus, once N̅u̅(\tilde{s}, \tilde{t},\tilde{L},Pr,K_{f},Reₘ) is known in tabular form, the optimal dimensionless fin spacing (\tilde{s}ₒₚₜ), thickness (\tilde{t}ₒₚₜ) and length (\tilde{L}ₒₚₜ) can be determined either by using a numerical optimization algorithm or by simply evaluating R′ₜ over a prescribed range for \tilde{s}, \tilde{t} and \tilde{L}, and locating its minimum value (R′_{t,min}). Then, their dimensional counterparts follow from Eqs. 27, 28 and 29, respectively.

It is emphasized that the optimization process does not require the conjugate problem to be solved multiple times. It requires only the knowledge of the table N̅u̅(\tilde{s},\tilde{t},\tilde{L},Pr,K_{f},Reₘ) over the parameter space that is relevant for a specific application. This fact allows the optimal fin spacing, thickness and length to be computed in a fraction of the time that is required by a brute-force CFD optimization.

Moreover, the present analysis allows to calculate either the global optimal dimensionless spacing, thickness and length of the fins when \tilde{s}, \tilde{t} and \tilde{L} are unconstrained as per above, or their local optimal values (\tilde{s}_{opt,l},\tilde{t}_{opt,l},\tilde{L}_{opt,l}) when a more manufacturing-friendly local optimal solution, although with higher R′ₜ, is of interest [5].

### 3.4 Tabulation of N̅u̅

The tabulation of the conjugate mean Nusselt number may be performed using FLUENT® in combination with ANSYS Workbench®. This combination of software packages is useful due to the large number of cases that had to be investigated and that the latter allows the set up and execution using FLUENT® of parametric models with multiple operating points each.

In the present analysis, each parametric model had fixed values for \tilde{t},\tilde{L},Pr,K_{f} and Reₘ, and the different operating points where obtained by varying \tilde{s}. It must be emphasized however that given that \tilde{w}ᵢₙ is the prescribed quantity at the inlet of the domain, Reₘ is actually a dependent variable. Thus, in order to ensure constant Reₘ for all of the operating points at each parametric model, \tilde{w}ᵢₙ was adjusted iteratively for each value of \tilde{s} such that the computed Reₘ was equal to its prescribed value.

A first estimate of \tilde{w}ᵢₙ was obtained as follows. Given that for the case at hand \tilde{w}ᵢₙ=\overline{\tilde{w}}, from the definition of the apparent friction factor

$${f}_{app} = 2 \frac{Δ p {D}_{h}}{L ρ {\overline{w}}^{2}} \qquad ( 72 )$$

and Eqs. 35, 36 and 40, it follows that

$${f}_{app} {Re}_{{D}_{h}} = \frac{8}{\tilde{L} {\tilde{w}}_{i n}} {( \frac{\tilde{s}}{\tilde{s} + 1} )}^{2} \qquad ( 73 )$$

Moreover, from Ref. [9] we know that

$${f}_{a p p} {Re}_{{D}_{h}} \approx 4 [ \frac{3.44}{\sqrt{{L}^{+}}} + ( \frac{1.25}{4 {L}^{+}} + \frac{{fRe}_{{D}_{h}}}{4} - \frac{3.44}{\sqrt{{L}^{+}}} ) / ( 1 + \frac{0.00021}{{L}^{+ 2}} ) ] \qquad ( 74 )$$

where the Poiseuille number (fRe_{D}_{ₕ}) [9] is given by the expression

$$\begin{matrix}f {Re}_{{D}_{h}} = 96 ( 1 - 1.3 \; 553 \tilde{s} + 1.9 \; 467 {\tilde{s}}^{2} - 1.7 \; 012 {\tilde{s}}^{3} + 0.9 \; 564 {\tilde{s}}^{4} - 0.2 \; 537 {\tilde{s}}^{5} ) & ( 75 ) \\ {L}^{+} = \frac{L}{{D}_{h} {Re}_{{D}_{h}}} & ( 76 ) \end{matrix}$$

is the dimensionless length of the fins based on the nondimensionlization of the streamwise coordinate for the hydrodynamic entrance region in the literature. Combining, Eqs. 34-36, 40, 73, 74 and 76, it follows that

$$\frac{2}{\tilde{L}} {( \frac{\tilde{s}}{\tilde{s} + 1} )}^{2} \approx {\tilde{w}}_{i n} [ \frac{3.44}{\sqrt{{L}^{+}}} + ( \frac{1.25}{4 {L}^{+}} + \frac{f {Re}_{{D}_{h}}}{4} - \frac{3.44}{\sqrt{{L}^{+}}} ) / ( 1 + \frac{0.00021}{{L}^{+ 2}} ) ] \qquad ( 77 )$$

where in terms of the presented dimensionless parameters

$${L}^{+} = \frac{\tilde{L}}{{\tilde{w}}_{i n} {Re}_{m}} {( \frac{ 2 \tilde{s}}{\tilde{s} + 1} )}^{- 2} \qquad ( 78 )$$

Thus, Eq. 77 is a transcendental equation with only unknown \tilde{w}ᵢₙ and Reₘ is the independent variable.

The conjugate mean Nusselt number was computed for \tilde{s}=[38.4E−3, 60.2E−3], \tilde{t}=[3.40E−3, 34.01E−3], \tilde{L}=2.41, Reₘ=1.42E8, Pr=0.7 and K_{f}=1.60E4. The corresponding results are presented in Section 3.5 along with comments for the chosen values of the dimensionless parameters.

The execution process of the parametric models is as follows. Starting from the first operating point of each model, ANSYS Workbench® updates the geometry of the domain using the prescribed \tilde{s}, \tilde{t} and \tilde{L}. Then, it discretizes the resulting domain with a structured mesh with approximately 1.56 million elements. Next, it updates the corresponding FLUENT® model with the new mesh and the prescribed \tilde{w}ᵢₙ, Pr and K_{f}. Then, FLUENT® initializes the solution using constant values for the unknown variables, i.e., Ũ, \tilde{T} and \tilde{T}_{f}. Consequently, FLUENT® iteratively solves the conjugate problem employing the coupled pseudo transient solver and second-order upwind scheme [1]. The solution process stops when the residuals for the computed Reₘ and N̅u̅ are both less than 1E−6. Then, the above process is repeated for the remaining operating points with the exception that the solution is initialized by interpolating the solution of the previous operating point in the new computational domain to accelerate convergence.

Due to the large number of cases, mesh independence was verified only for the parametric models for \tilde{t}−=3.4E−3 and 11.91E−3. These specific values for \tilde{t} were chosen because the latter provides the highest N̅u̅ for every \tilde{s}, and the former was used to verify that ∂N̅u̅/∂\tilde{t}>0 for \tilde{t}<11.91E−3. To perform this task, the models were executed as per above but the domains of the operating points were discretized with approximately 3.27 million elements instead of 1.56 million elements. The maximum discrepancies for the computed Reₘ and N̅u̅were less than 0.09% and 0.01%, respectively.

### 3.5 Results

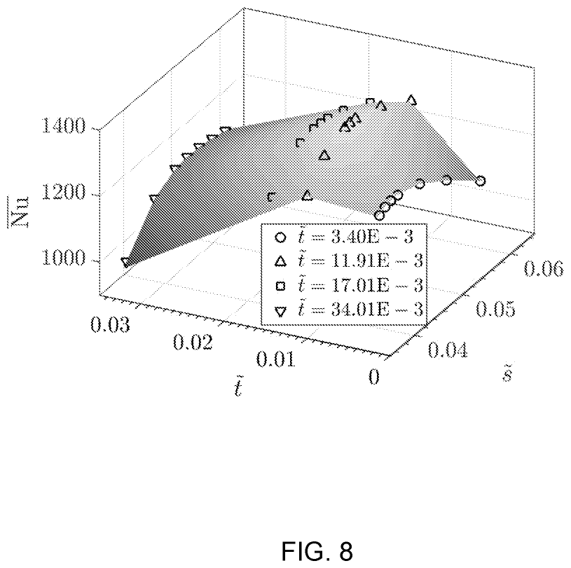

FIG. 8 presents the computed conjugate mean Nusselt numbers, indicated with markers, and a linear interpolation of the results over the remaining parameter space of the dimensionless fin spacing and thickness. The prescribed values for the dimensionless parameters were chosen considering the case of a 29.4 mm tall and 71 mm long copper-LFHS with s=[1.13 mm, 1.77 mm] and t=[0.1 mm, 1 mm] that is cooled by air and the pressure drop across the LFHS is 42.8 Pa. It is emphasized though that the computed N̅u̅ are not restricted to this particular case because the analysis is nondimensional.

The results exhibit the correct behavior given that the computed N̅u̅ is strictly concave. That was anticipated for two reasons. First, the analysis considers the efficiency to heat transfer per unit width of the LFHS, and thus for fixed channel width an increase in \tilde{t} comes at the expense of \tilde{s} and vice versa. Secondly, N̅u̅ is affected from both the convective and the caloric part of the thermal resistance. The convective part decreases monotonically as \tilde{t} increases, i.e., as the fin tends to become isothermal, and the caloric part increases monotonically as \tilde{s} decreases. Thus, the conjugate mean Nusselt number is a strictly concave function with respect to both \tilde{s} and \tilde{t}, and for the case at hand it attains a global maximum of approximately 1.39E3 at the vicinity of \tilde{s}ₒₚₜ=47.22E−3 and \tilde{t}ₒₚₜ=11.91E−3. Of course, the convective part of the thermal resistance might slightly benefit from an increase in \tilde{s} because the thermal boundary layers merge further downstream in the streamwise direction and the area of the prime surface increases too. However, these are secondary effects compared to those of \tilde{t}.

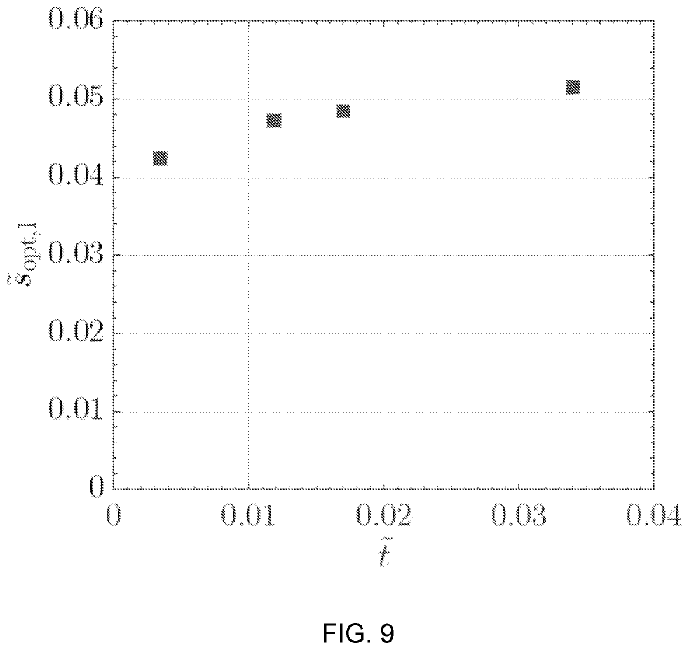

A second observation in FIG. 9 is that the local optimal value of the dimensionless fin spacing increases as \tilde{t} increases. This trend can be observed better in FIG. 9 that presents \tilde{s}_{opt,l} vs. \tilde{t} for the aforementioned values of the rest dimensionless parameters. \tilde{s}_{opt,l} is strictly increasing with respect to \tilde{t} and this fact is very important because it reduces significantly the range of values of \tilde{s} that need to be investigated for an optimization since \tilde{s}_{opt,l} is bounded from below.

### 3.6 Thermal Resistance Minimization Example

The steps used to determine the optimal (global or local) fin spacing, thickness and length that minimize R′ₜ of a particular longitudinal-fin heat sink are as follows. First, Pr, K_{f} and Reₘ are computed from Eqs. 31, 33 and 34, respectively, for the prescribed geometrical parameters of the LFHS (H), thermophysical properties of the fluid and the fin (μ,ρ,cₚ,k,k_{f}) and pressure drop across the heat sink (Δp). Then, R′ₜ is evaluated from Eq. 71 over a prescribed range of \tilde{s}, \tilde{t} and \tilde{L} utilizing the precomputed table of N̅u̅(\tilde{s},\tilde{t},\tilde{L},Pr,K_{f},Reₘ). Next, R′_{t,min} is located along with the corresponding optimal values (global or local) of \tilde{s}, \tilde{t} and \tilde{L}. Then, the dimensional optimal fin spacing, thickness and length follow from Eqs 27, 28 and 29. At this point, care should be exercised because since the present analysis minimizes the thermal resistance per unit width of the LFHS, the computed optimal values of the fin spacing and thickness do not in general yield integer numbers of fins and channels for a prescribed width. One solution is to choose values for s and t in the vicinity of their computed optimal values such that the numbers of fins and channels are integers.

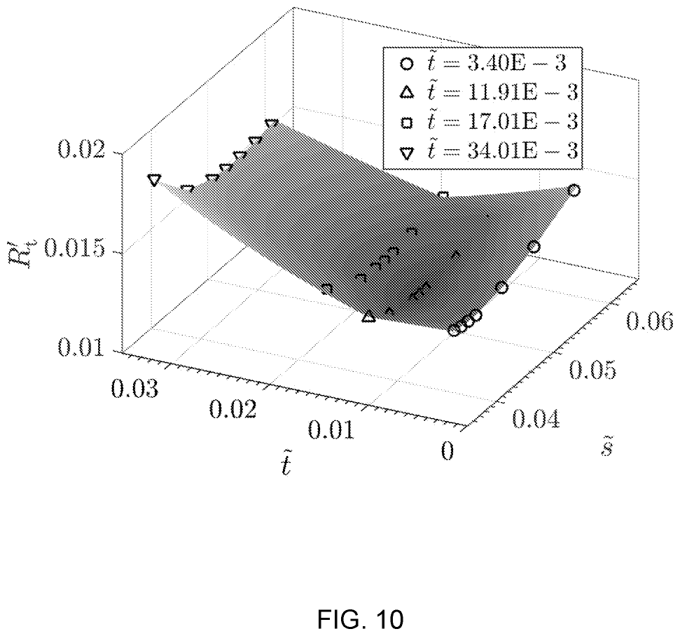

FIG. 10 presents the computed R′ₜ vs \tilde{s} and \tilde{t} for the aforementioned values of the dimensionless parameters. Given that R′ₜ is inversely proportional to N̅u̅, they have the same sₒₚₜ=47.22E−3 and \tilde{t}ₒₚₜ=11.91E−3. The corresponding global optimal dimensional fin spacing and thickness are approximately equal to 1.39 mm and 0.35 mm, respectively. These values correspond to 51 channels and 52 fins for W=89 mm.

Finally, it is emphasized that we intentionally choose to present this general optimization method and not to provide only tables of \tilde{s}ₒₚₜ(Pr,K_{f},Reₘ), \tilde{t}ₒₚₜ(Pr,K_{f},Reₘ) and \tilde{L}ₒₚₜ(Pr,K_{f},Reₘ) along with the corresponding values of N̅u̅, because these cases might not be feasible from manufacturing perspective when they are converted to dimensional quantities for some particular cases. Also, we note that the present analysis assumes that W>>s+t and that the base of the LFHS is isothermal. However, if a particular case does not meet these assumptions the results from the present analysis may serve as a useful starting point for a CFD brute-force optimization.

### 4 SUMMARY

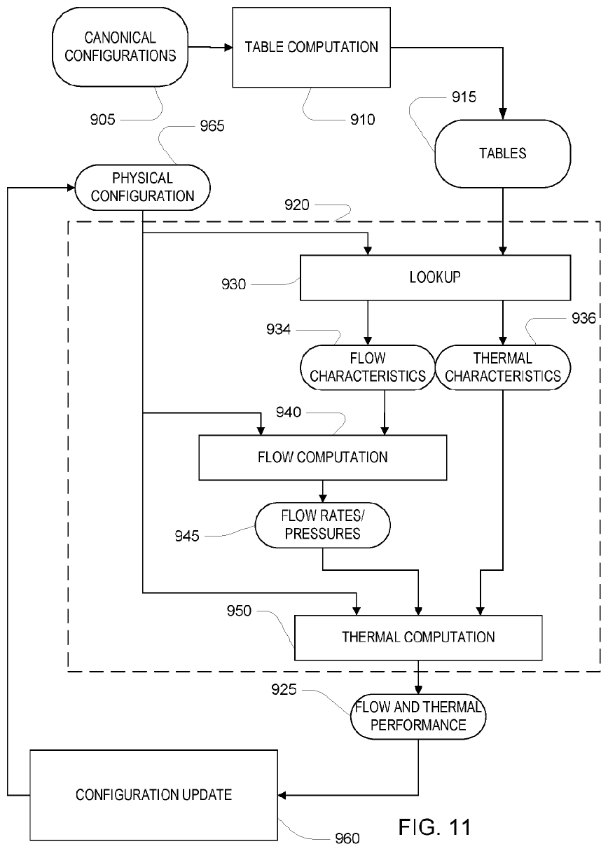

Referring to FIG. 11, one or more embodiments described above can be summarized by the diagram in the figure. The table computation 910 represents the precomputation of the tables 915 of flow and thermal characteristics associated with each configuration of the canonical configurations 905. Generally, the initial physical configuration 965 of the heat sinks for a system is analyzed in a procedure 920 to determine the flow and thermal performance 925 of the physical configuration. The configuration update 960 is applied to optimize the objective function yielding a new physical configuration 965, and this process is iterated until a optimum is achieve or some other stopping criterion is reached. The procedure 920 makes use of the precomputed tables 915 to achieve the low computation of the present approach. A lookup 930 transforms the physical configuration 965 to a corresponding canonical configuration, and retrieves the corresponding record from the tables 915. The quantities in the retrieved record are then mapped back to flow characteristics 934 and thermal characteristics 936 of the physical configuration. A flow computation 940 makes use of the physical configuration 965 and the flow characteristics 934 determined by the lookup 930, yielding the flow rates and pressures 945 for the configuration. Then, the thermal characteristics 936 determined by the lookup 930 are used in combination with the computed flow rates and pressures in a thermal computation 950 to determine the overall flow and thermal performance 925 of the physical configuration 965.

Embodiments of the approaches described above may use software, which may includes instructions for a data processing system that are stored on a non-transitory machine-readable medium. The instructions may be machine or higher-level language instructions for a general-purpose processor, a virtual processor, a graphical processor unit, or the like. Some embodiments may make use of special-purpose circuitry, for instance, Application Specific Integrated Circuits (ASICs), for instance to augment the computation performed by the data processing system. It should be recognized that the computation of the tables is not necessarily performed in the same computer as the optimization procedure. The tables themselves can be considered to impart functionality to the data processing system that performs the flow and thermal performance computation. In some embodiments, the tables may be provided in the form of software, for example, as objects of an object-oriented programming language that implement methods for accessing precomputed CFD information to yield thermal and performance characteristics for particular physical configurations.

It is to be understood that the foregoing description is intended to illustrate and not to limit the scope of the invention, which is defined by the scope of the appended claims. Other embodiments are within the scope of the following claims.

### REFERENCES

[1] ANSYS Fluent Theory Guide, ANSYS Inc., November 2013.
[2] Longitudinal-Fin Heat Sink Conjugate Mean Nusselt Numbers for Simultaneously Developing Flow, Electronic Lab Notebook Tufts data center
[3] Adrian Bejan and Enrico Sciubba. The optimal spacing of parallel plates cooled by forced convection. International Journal of Heat and Mass Transfer, 35(12):3259-3264, 1992.
[4] A. Husain and Kwang-Yong Kim. Shape optimization of micro-channel heat sink for micro-electronic cooling. IEEE Transactions on Components and Packaging Technologies, 31(2):322-330, June 2008.
[5] M. Iyengar and A. Bar-Cohen. Design for manufacturability of sise parallel plate forced convection heat sinks. IEEE Transactions on Components and Packaging Technologies, 24(2):150-158, June 2001.
[6] R. W. Knight, J. S. Goodling, and D. J. Hall. Optimal thermal design of forced convection heat sinks-analytical. Journal of Electronic Packaging, 113(3):313-321, Sep. 1, 1991.
[7] R. W. Knight, D. J. Hall, J. S. Goodling, and R. C. Jaeger. Heat sink optimization with application to microchannels. IEEE Transactions on Components, Hybrids and Manufacturing Technology, 15(5):832-842, October 1992.
[8] Ji Li and G. P. Peterson. Geometric optimization of a micro heat sink with liquid flow. IEEE Transactions on Components and Packaging Technologies, 29(1):145-154, March 2006.
[9] Gregory E Nellis and Sanford A. Klein. Heat Transfer. Cambridge University Press, New York, 2009.
[10] E. M. Sparrow, B. R. Baliga, and S. V. Patankar. Forced convection heat transfer from a shrouded fin array with and without tip clearance. Journal of Heat Transfer, 100(4):572-579, Nov. 1, 1978.
[11] P. Teertstra, M. M. Yovanovich, and J. R. Culham. Analytical forced convection modeling of plate fin heat sinks. Journal of Electronics Manufacturing, 10(04):253-261, 2000.
[12] Arel Weisberg, Haim H. Bau, and J. N. Zemel. Analysis of microchannels for integrated cooling. International Journal of Heat and Mass Transfer, 35(10):2465-2474, 1992.

What is claimed is:

1. A method for determining a configuration of one or more thermal transfer elements of a thermal system, the method comprising:
accepting a lumped element representation of the thermal system, the representation including a plurality of parameters characterizing one or more thermal transfer elements and the configuration of the system;
optimizing values of the parameters characterizing the one or more thermal transfer elements, including repeating for each of the thermal transfer elements, using the values of parameters characterizing said element to access stored data characterizing a canonical configuration corresponding to the thermal transfer element, and transforming the accessed data characterization to represent characteristics of the thermal transfer element of the thermal system;
using the transformed data and the lumped element representation to determine fluid and heat flow characteristics of the lumped representation of the thermal system; and
updating values of the parameters characterizing the one or more thermal transfer elements.

2. The method of claim 1 further comprising: computing and storing data characterization of a plurality of canonical configurations of thermal transfer elements.

3. The method of claim 1 wherein the thermal system comprises electronic circuitry and the thermal transfer elements comprise heat sinks.

4. The method of claim 1 wherein the values of the parameters characterizing the thermal transfer elements comprise dimensional values of said elements.

5. The method of claim 1 wherein the values of the parameters characterizing the thermal transfer elements comprise thermophysical values of said elements.

6. The method of claim 1 wherein the canonical configurations are specified by dimensionless quantities.

7. The method of claim 6 wherein transforming the data characterization of the canonical configuration includes using a relationship between dimensionless quantities specifying the canonical configuration and dimensional values characterizing the thermal element of the system.

8. The method of claim 1 wherein the lumped element representation comprises a flow network model.

9. The method of claim 2 wherein computing the data characterization of a canonical configuration of a thermal transfer element comprises applying a computational fluid dynamics procedure.

10. The method of claim 1 wherein optimizing the values of the parameters comprises applying an iterative optimization procedure.

11. The method of claim 10 wherein updating the values of the parameters comprises selecting values to improve a utility of the thermal system configured according to the values.

12. The method of claim 1 wherein optimizing the values comprises optimizing a utility of the thermal system.

13. The method of claim 12 wherein the utility represents at least one of an input temperature of a cooling fluid, a temperature of a device cooled by the thermal transfer elements, and a weight of the thermal transfer elements.

14. A non-transitory machine-readable medium comprising instructions stored thereon, execution of the instructions causing a data processing system to perform all the steps of any one of claim 1 through claim 13.

15. A data processing system configured to perform all the steps of any one of claim 1 through claim 13.
